(19) United States
(12) Patent Application Publication
(10) Pub. No.: US 2023/0126278 A1
(43) Pub. Date: Apr. 27, 2023

(54) RECORDING COMPONENT DATA

(71) Applicant: ASM Assembly Systems GmbH & Co. KG, Munich (DE)

(72) Inventor: Sylvester DEMMEL, Bad Aibling (DE)

(21) Appl. No.: 17/970,642

(22) Filed: Oct. 21, 2022

(30) Foreign Application Priority Data
Oct. 21, 2021 (DE) 10 2021 127 407.9

(51) Int. Cl. H05K 13/08; H05K 13/04

(52) U.S. Cl. CPC H05K 13/0812; H05K 13/0404

(57) ABSTRACT

Data associated with an electronics component within a placement process performed by a placement machine is recorded by using the camera to image a machine-readable code located on the component tape which expresses data associated with an electronics component to be picked up by the placement head. The camera could be located within the feeder or the placement head.

This invention relates to feeders for placement machines, placement heads for placement machines, placement machines fitted with such feeders or placement heads, and methods of recording data associated with an electronics component within a placement process performed by a placement machine.

### BACKGROUND AND PRIOR ART

The present invention relates in general to the technical field of equipping component carriers with electronic components.

The production of electronic subassemblies occurs typically with so-called placement machines, by which electronic components are removed from a component supply device in an automated manner and placed on a component carrier such as, for example, a printed circuit board. A transfer of electronics components from the component supply device to their respective placement position occurs by means of a component handling device, for example, a so-called placement head. In most cases, such a transfer of an electronics component occurs by means of a single handling device, commonly referred to as placement head.

It is advantageous for operators of such placement equipment to be able to track for components during the placement process. This means monitoring and recording the exact location a particular component is placed onto a board, with this information being linked to the serial number of the end product. To this end, a unique ID is assigned to each component, and this single component is passed along with the manufacturing process. Today, single component tracking can be used when placing components directly from a wafer. In this case, the wafer is assigned a unique wafer ID, which is known to the operator, and due to referencing on the wafer, the exact column and row from which a component is picked is known. Additionally, the position at which the component is placed on a board is known through the placement machine operation, and finally the board itself is provided with a unique PCB ID in the form of a machine-readable code such as a barcode, QR code or the like, which can be read using a downward-looking PCB registration camera. A unique ID could be provided on the bottom of a PCB and read with a barcode reader, or, if there is a radio-frequency identification (RFID) tag on the PCB, this could be read with an associated RFID reader. In this way, all variables in the placement operation can be tracked.

However, a problem exists in that while it is possible to identify and track unique electronics components when picked from a wafer using referencing techniques, it is not possible to do so when the electronics components are instead stored within a component-feeding tape, which is often preferred since the use of tape-housed electronics components generally provides higher placement performance. In such systems, electronics components are stored in pockets provided along the length of the tape, with the tape being stored on a reel and fed to the placement machine using a feeder, as is well-known in the art per se. Tapes may be provided with identification markings in the form of machine-readable codes such as barcodes, QR codes or the like (hereafter generally referred to as “codes”), and a degree of tracking may be possible by using a camera mounted at the placement head to read the tape code before picking each electronics component. Such a component tape 1 is schematically shown in FIG. 1. As shown, component tape 1 is of elongate form, and includes a linear array of pockets 2 arranged along its length for holding electronics components (not shown) therein. The array of pockets is closed by a foil strip 3, which is attached to the upper surface of tape 1 by lines of adhesive 4. Before electronics components can be picked up from the pockets 2, it is necessary to remove or cut open the foil strip 3, as is well-known in the art. A plurality of holes 5 are arranged along the length of tape 1 beside the pocket array, for engagement with a driving pinwheel (not shown) accommodated within the feeder. Adjacent each pocket 2 and associated therewith is a printed machine-readable code 6, such as a QR-code as shown. This machine-readable code expresses data associated with an electronics component located within the associated pocket 2.

The machine-readable codes 6 may be read by a downward-looking PCB-registration camera which is commonly provided within placement machines. However, the distance between the PCB-registration camera and the presentation area of the feeder (from where the electronic components are picked-up), is different to the distance between the electronic component's pocket and the machine-readable code on the tape. Therefore the placement head has to travel an additional distance to read the tape code before picking up the electronics component. This additional travel reduces the placement performance very significantly.

The present invention seeks to provide a method and apparatus for obtaining electronics component data from the machine-readable code located in component tape, without reducing the placement performance. In accordance with the present invention, this aim is achieved by providing a dedicated camera, located either in a feeder or in the placement head, for imaging the machine-readable codes of a component tape.

### SUMMARY OF THE INVENTION

In accordance with a first aspect of the present invention there is provided a feeder for a placement machine, the feeder adapted to feed a component tape housing electronics components to a presentation area of the feeder, the placement machine being operative to pick electronics components from the component tape in the vicinity of the presentation area and place the picked components onto a workpiece, wherein the feeder comprises a camera for imaging machine-readable codes located on the component tape.

In accordance with a second aspect of the present invention there is provided a placement machine fitted with the feeder of the first aspect.

In accordance with a third aspect of the present invention there is provided a placement head for a placement machine, the placement machine being operative to pick electronics components with the placement head from a component tape in the vicinity of a presentation area of a feeder and place the picked components onto a workpiece, wherein the placement head comprises a camera for imaging machine-readable codes located on the component tape.

In accordance with a fourth aspect of the present invention there is provided a placement machine fitted with the placement head of the third aspect.

In accordance with a fifth aspect of the present invention there is provided a method of recording data associated with an electronics component within a placement process performed by a placement machine, comprising the steps of:

providing a feeder adapted to feed a component tape which houses electronics components to a presentation area of the feeder,

providing a placement head within the placement machine, the placement head being operative to pick up electronics components from the component tape in the vicinity of the presentation area,

providing a camera within the placement machine, and

using the camera to image a machine-readable code located on the component tape which expresses data associated with an electronics component to be picked up by the placement head.

Other specific aspects and features of the present invention are set out in the accompanying claims.

### BRIEF DESCRIPTION OF THE DRAWINGS

The invention will now be described with reference to the accompanying drawings (not to scale), in which:

FIG. 1 schematically shows, in perspective view, a portion of a known component tape;

FIG. 2 schematically shows, in sectional side view, a feeder in accordance with a first embodiment of the present invention; and

FIG. 3 schematically shows, in sectional side view, a placement machine with a placement head in accordance with a further embodiment of the present invention.

### DETAILED DESCRIPTION OF THE PREFERRED EMBODIMENTS OF THE INVENTION

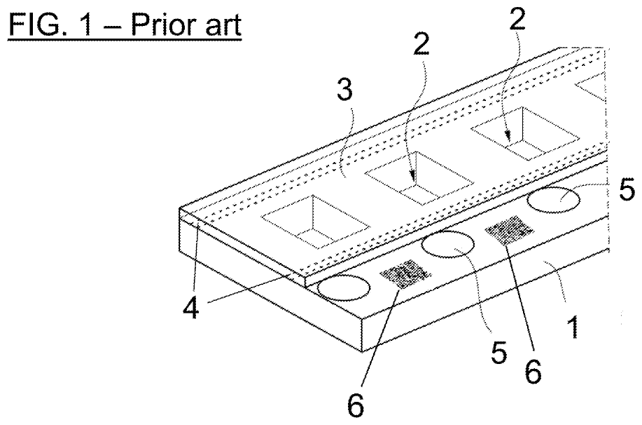

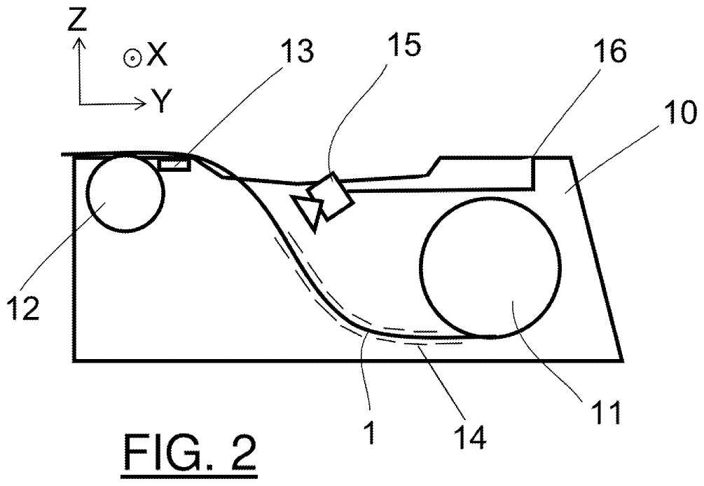

FIG. 2 schematically shows, in sectional side view, a feeder 10 in accordance with a first embodiment of the present invention. The feeder 10 is adapted to engage with a placement machine (not shown), as is generally known in the art. The feeder 10 is adapted to feed a component tape 1, for example similar to that shown in FIG. 1, which houses electronics components (not shown in FIG. 2), to a presentation area 13 of the feeder. The placement machine is operative to pick electronics components from the component tape 1 in the vicinity of (i.e. overlying) the presentation area 13 and place the picked components onto a workpiece (not shown). In an initial state, the component tape 1 is stored on a component tape reel 11 which is accommodated within the feeder 1 on a reel mount (not shown) such as a spindle. The component tape 1 is guided from the component tape reel 11 to the presentation area 13 by a tape guide, here in the form of a guidance channel 14. The component tape 1 is fed through the feeder by a drivable pin wheel 12 which engages with holes 5 (see FIG. 1) of the component tape 1, the pin wheel 12 being located after the presentation area 13 in the direction of tape feeding. As is generally known in the art, the feeder 10 may also be provided with means (not shown) to remove the foil strip 3 (see FIG. 1) from the component tape 1.

The feeder 10 comprises a camera 15 arranged for imaging machine-readable codes (6, see FIG. 1) located on the component tape 1. As shown, the camera 15 is mounted so as to point towards the upper surface of the component tape 1 at a point adjacent the tape guide. With this arrangement, it can be seen that the camera 15 will image a machine-readable code 6 associated with a component pocket (2, see FIG. 1) in advance of the component pocket currently in the vicinity of the presentation area 13. With this positioning of the camera 15, there is no risk of its interfering with travel of a placement head (not shown) during a placement operation. The camera 15 is communicatively connected to a camera interface 16 which can engage with a corresponding interface (not shown) of the placement machine, which in turn is communicatively connected to a control means for the placement machine, such as a locally or remotely located computer, processor laptop or the like. The camera interface 16 could be provided solely for the camera operation, or alternatively also provide an interface for other feeder functions, such as control of the pin wheel 12 as is generally known in the art. The control means can thus both control operation of the camera 15, and process imaging data received from the camera 15. In particular, the control means can extract component data from the imaged machine-readable code 6 and associate it with the correct pocket 2 of the component tape 1. Alternatively or additionally, a local control means (not shown), such as a microcontroller, may be provided with the camera 16 at the feeder to decode the captured images and pass the component information data to the placement machine via camera interface 16.

The camera 15 comprises a nano camera sensor, such as a wafer-scale packed nano camera sensor. Such cameras are known in the art per se, for example similar units are currently used in the sensors for optical PC mice. In the case of the optical PC mouse, a small camera with resolution in the range from 16×16 up to 32×32 pixels is used, together with some digital signal processing (DSP) to calculate the optical flow, direction, and amount of the mouse displacement. Today, higher resolution nano-optical camera sensors with micro-optics are available that have an overall size in the millimetre scale, and are currently used for various applications such as endoscopy, robotics, internet of things (IoT), wearable devices (eye tracking, virtual/augmented reality, gesture recognition).

In order to improve imaging quality, in some embodiments an illumination device (not shown) may be provided proximate the camera 15 for illuminating the machine-readable codes 6 during imaging. Such an illumination device could for example comprise one or more light emitting diodes (LEDs), under the operative control of the control means.

With such an arrangement there would be no performance loss when reading the machine-readable code 6.

In alternative embodiments, the feeder need not include a reel mount to accommodate a component tape reel, but instead could form part of a modular system, in which case it would comprise an interface for connection to a cartridge in use, the cartridge comprising a reel mount for receiving the component tape reel.

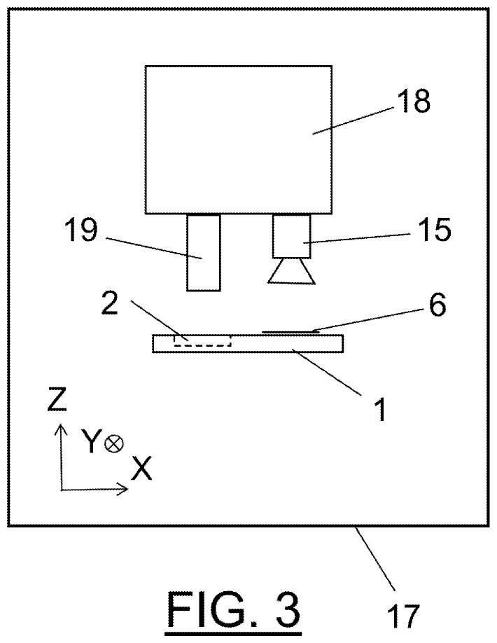

FIG. 3 schematically shows, in sectional side view, a placement machine 17 with a placement head 18 in accordance with a further embodiment of the present invention. As is well-known in the art per se, the placement head 18 is movable with respect to the placement machine 17 both vertically (parallel to the Z-axis shown), and horizontally (parallel to the X, Y axes shown), so that it can travel between the presentation area of a feeder to the required location of a board. The placement head 18 includes a component-holding tool adapted to selectively pick up and hold an electronics component (not shown) from a pocket 2 of the component tape 1 at the presentation area of a feeder, in this case a nozzle 19 which can pick-up an electronics component by applying a vacuum thereto. The placement head 18 comprises a camera 15 for imaging machine-readable codes 6 located on the component tape 1. The camera 15 may be similar to that previously-described with reference to FIG. 2, and communicatively connected to a control means (not shown) locally or remotely located with respect to the placement machine 17, such as a computer, processor, laptop or the like, and may also be provided with a local control means such as a microcontroller to decode the captured images and pass the component information data to the control means. The or each control means can therefore control operation of the camera 15 and process imaging data received from the camera 15. In particular, the control means can extract component data from the imaged machine-readable code 6 and associate it with the correct pocket 2 of the component tape 1. The camera 15 is disposed in a downwardly-pointing orientation so as to image the machine-readable codes 6 from above. The camera 15 is horizontally spaced from the nozzle 19 in the X direction shown, i.e. in the direction of the width of the component tape 1. The spacing is such that, during a pick-up operation in which the nozzle picks up an electronics component from a pocket 2 of the component tape 1, the camera 15 is positioned directly above a machine-readable code 6 associated with the electronics component being picked up by the nozzle 1. In this case, the camera 15 images a machine-readable code 6 which is associated with the pocket 2 currently being picked from.

The above-described embodiments are exemplary only, and other possibilities and alternatives within the scope of the invention will be apparent to those skilled in the art. For example, various types of placement heads could be employed, including rotary heads

### REFERENCE NUMERALS USED

1—Component tape
2—Pockets
3—Foil strip
4—Adhesive
5—Holes
6—Machine-readable codes
10—Feeder
11—Component tape reel
12—Pin wheel
13—Presentation area
14—Guidance channel
15—Camera
16—Camera interface
17—Placement machine
18—Placement head
19—Nozzle

1. A feeder for a placement machine, the feeder adapted to feed a component tape housing electronics components to a presentation area of the feeder, the placement machine being operative to pick electronics components from the component tape in the vicinity of the presentation area and place the picked components onto a workpiece, wherein the feeder comprises a camera for imaging machine-readable codes located on the component tape.

2. The feeder of claim 1, wherein the component tape is stored on a component tape reel, and the feeder comprises a tape guide for guiding the component tape from the component tape reel to the presentation area.

3. The feeder of claim 2, comprising a reel mount for receiving the component tape reel.

4. The feeder of claim 2, comprising an interface for connection to a cartridge in use, the cartridge comprising a reel mount for receiving the component tape reel.

5. The feeder of claim 2, wherein the camera is located in the feeder to image machine-readable codes located on the component tape adjacent the tape guide.

6. The feeder of claim 1, comprising an illumination device for illuminating the machine-readable codes during imaging.

7. The feeder of claim 1, wherein the camera comprises a nano camera sensor.

8. A placement machine fitted with the feeder of claim 1.

9. A placement head for a placement machine, the placement machine being operative to pick electronics components with the placement head from a component tape in the vicinity of a presentation area of a feeder and place the picked components onto a workpiece, wherein the placement head comprises a camera for imaging machine-readable codes located on the component tape.

10. The placement head of claim 9, wherein the camera is disposed in a downwardly-pointing orientation so as to image the machine-readable codes from above.

11. The placement head of claim 10, comprising a component holding tool adapted to selectively hold an electronics component, and wherein the camera is horizontally spaced from the component holding tool.

12. The placement head of claim 11, wherein the camera is horizontally spaced from the component holding tool such that, during a pick-up operation in which the component holding tool picks up an electronics component from a pocket of the component tape, the camera is positioned directly above a machine-readable code associated with the electronics component being picked up by the component holding tool.

13. The placement head of claim 9, wherein the camera comprises a nano camera sensor.

14. A placement machine fitted with the placement head of claim 9.

15. A method of recording data associated with an electronics component within a placement process performed by a placement machine, comprising the steps of:
providing a feeder adapted to feed a component tape which houses electronics components to a presentation area of the feeder,
providing a placement head within the placement machine, the placement head being operative to pick up electronics components from the component tape in the vicinity of the presentation area,
providing a camera within the placement machine, and
using the camera to image a machine-readable code located on the component tape which expresses data associated with an electronics component to be picked up by the placement head.

16. The method of claim 15, wherein the camera is located on the feeder.

17. The method of claim 15, wherein the camera is located on the placement head.
